(19) United States
(12) Patent Application Publication
(10) Pub. No.: US 2015/0021711 A1
(43) Pub. Date: Jan. 22, 2015

(54) SEMICONDUCTOR DEVICE

(71) Applicant: FUJI ELECTRIC CO., LTD., Kawasaki-shi (JP)

(72) Inventor: Akihiro JONISHI, Matsumoto-city (JP)

(21) Appl. No.: 14/507,138

(22) Filed: Oct. 6, 2014

Related U.S. Application Data
(63) Continuation of application No. PCT/JP2013/077641, filed on Oct. 10, 2013.

(30) Foreign Application Priority Data
Oct. 12, 2012 (JP) 2012-227527

(51) Int. Cl. H01L 29/78; H01L 29/06

(52) U.S. Cl. CPC H01L 29/78; H01L 29/0603
USPC 257/401

(57) ABSTRACT

A p diffusion region is selectively provided in a surface layer of an n⁻ diffusion region which is provided in the front surface of a p-type bulk substrate. A power supply potential is applied to the n⁻ diffusion region. A PMOS of a high-side driving circuit and a clamping PMOS are arranged in the n⁻ diffusion region. An intermediate potential is applied to the p diffusion region. An NMOS of the high-side driving circuit is arranged in the p diffusion region. The high-side driving circuit operates at a potential between an intermediate potential, which is a reference potential, and the power supply potential. The threshold voltage of the clamping PMOS is in the range of about −0.1 V to −0.6 V. A p+ source region and a gate electrode of the clamping PMOS are connected to a VB electrode.

### CROSS-REFERENCE TO RELATED APPLICATIONS

This application is a continuation of International Application No. PCT/JP2013/077641, filed on Oct. 10, 2013, which is based on and claims priority to Japanese Patent Application No. JP 2012-227527, filed on Oct. 12, 2012. The disclosure of the Japanese priority application and the PCT application in their entirety, including the drawings, claims, and the specification thereof, are incorporated herein by reference.

### BACKGROUND

1. Field of the Invention

The present invention relates to a semiconductor device.

2. Related Art

In recent years, a transformer or a photocoupler in which an input side and an output side are electrically insulated from each other has been known as a semiconductor element which is used to drive a gate of a switching element, such as an insulated gate bipolar transistor (IGBT) forming a power conversion bridge circuit, in an industrial inverter. In addition, in recent years, a high-voltage IC (HVIC) in which an input side and an output side are not electrically insulated from each other has been mainly used for a low-capacity inverter in order to reduce costs. See, for example, T. FUJIHIRA, et al., Proposal of New Interconnection Technique for Very High-Voltage IC's, Japanese Journal of Applied Physics, Jan. 1996, vol. 35 (Issue part 1), No. 11, pp. 5655-5663 and Jonathan Adams, “Bootstrap Component Selection For Control IC's,” [online], International Rectifier Japan), [Searched Sep. 24, 2012], Internet http://www.irf-japan.com/technical-info/designtp/dt98-2j.pdf (also referred to herein as Non-patent Document 2).

The circuit structure of a high-voltage IC according to the related art will be described. FIG. 23 is a circuit diagram illustrating the high-voltage IC. A high-voltage IC 200 illustrated in FIG. 23 is a circuit for driving first and second IGBTs 101 and 102 which form one phase of a power conversion bridge circuit. The first and second IGBTs 101 and 102 are connected in series between a high-voltage main power supply (positive electrode side) Vdc and a ground potential GND which is the negative electrode side of the main power supply. AVS terminal is connected to a connection point 105 between the first IGBT 101 and the second IGBT 102. The connection point 105 is an output point of a bridge circuit formed by the first and second IGBTs 101 and 102.

The high-voltage IC 200 generally includes a high-side driving circuit 110, a low-side driving circuit (not illustrated), a level shifter 115, and a control circuit 116. The high-side driving circuit 110 includes, for example, a gate driving circuit 111 and a level shift resistor 119. The gate driving circuit 111 is a complementary MOS (CMOS) in which a high-side p-channel MOSFET (insulated gate field effect transistor; hereinafter, referred to as a PMOS) 112 and a low-side n-channel MOSFET (hereinafter, referred to as an NMOS) 113 are complementary. Reference numerals 103, 104, and 117 denote a free-wheeling diode (FWD).

The control circuit 116 operates at a ground potential GND as a reference and generates a low-level on/off signal for turning on and off the first IGBT 101 and a low-level on/off signal for turning on and off the second IGBT 102. The level shifter 115 converts the low-level on/off signal generated by the control circuit 116 into a high-level on/off signal to be input to the gate of the first IGBT 101.

The operation of the high-voltage IC 200 when the high-side first IGBT 101 is driven will be described. The control circuit 116 generates the low-level on/off signal for turning on and off the first IGBT 101. The low-level on/off signal is converted into the high-level on/off signal by the level shifter 115 and is then input to the high-side driving circuit 110. The high-side driving circuit 110 operates at a potential between the intermediate potential VS, as a reference potential, and the power supply potential VB. The power supply potential VB is, for example, about 15 V higher than the intermediate potential VS.

The on/off signal which is input from the control circuit 116 to the high-side driving circuit 110 is input to the gate of the first IGBT 101 on the high side through a NOT circuit and the gate driving circuit 111 provided on the rear side of the NOT circuit. The first IGBT 101 is turned on and off on the basis of the on/off signal from the control circuit 116. While the high-voltage IC 200 is operating, the intermediate potential VS applied to the VS terminal varies between 0 V and Vdc.

As a method for manufacturing (producing) the high-voltage IC 200 at a low cost, an IC process is suitable which uses a self-isolation technique that can use an inexpensive bulk substrate and does not require a special element isolation process. The structure of the high-voltage IC 200 manufactured by the self-isolation IC process will be described. FIG. 24 is a plan view schematically illustrating the planar structure of a high-voltage IC according to the related art. FIG. 25 is a cross-sectional view illustrating a cross-sectional structure taken along the cutting line AA-AA′ of FIG. 24.

As illustrated in FIGS. 24 and 25, a p-type bulk substrate 201 includes a high-side driving circuit region 210 in which a high-side driving circuit is arranged, a high-voltage isolation region 215 which surrounds the high-side driving circuit region 210, and a low-side region 216 which surrounds the high-voltage isolation region 215. A level shifter 115 is provided in the high-voltage isolation region 215. A low-side region 216 is a portion except for the high-side driving circuit region 210 and a portion of the high-voltage isolation region 215 in which the level shifter 115 is formed. The control circuit 116 is arranged in the low-side region 216. The high-side driving circuit region 210 is separated from the low-side region 216 by the high-voltage isolation region 215 and a high potential that is higher than that applied to the low-side region 216 by 600 V or more can be applied to the high-side driving circuit region 210.

An n− diffusion region 202 is selectively formed in a surface layer of the p− type bulk substrate 201. The n− diffusion region 202 is provided so as to extend from the high-side driving circuit region 210 to the high-voltage isolation region 215. A high-side driving circuit is formed in the n− diffusion region 202 in the high-side driving circuit region 210. Specifically, a lateral PMOS 212 and a lateral NMOS 213 which form a gate driving circuit are formed in a surface layer of the n− diffusion region 202.

The NMOS 213 is formed in a p− diffusion region 203 which is provided in the surface layer of the n− diffusion region 202. In addition, a p− region 204 is provided in the low-side region 216 outside the n− diffusion region 202 which is provided in the surface layer of the p-type bulk substrate 201. The ground potential GND is applied to the p-type bulk substrate 201 and the p− region (hereinafter, referred to as a p− GND region) 204. A high-side power supply potential VB is applied to the n− diffusion region 202. The intermediate potential VS is applied to the p− diffusion region 203.

As the high-voltage IC, a device has been proposed in which a high potential gate driving circuit portion and a level shift circuit portion are provided on the same semiconductor substrate 1 of a different conductivity type, at least one lateral MOSFET is formed in the gate driving circuit portion, and an embedded insulating film for suppressing a parasitic element is selectively provided in a direction parallel to the main surface of the semiconductor substrate below the source and drain regions of the lateral MOSFET. See, for example, Japanese Patent Application Publication No. JP 2008-288476 A.

As another high-voltage IC, the following device has been proposed. The device includes an sgPMOS transistor as an electrostatic protection circuit connected to between an input/output terminal and a ground terminal. The transistor includes a source and a gate which are connected to the input/output terminal and a drain which is connected to the ground terminal. The drain of the transistor has a double diffusion structure including a first P-TYPE drain diffusion layer and a second P-TYPE drain diffusion layer. See, for example, Japanese Patent Application Publication No. JP 2009-105392 A.

As another high-voltage IC, the following device has been proposed. The device includes a p− semiconductor substrate in which a high-breakdown-voltage element region in which a high-breakdown-voltage element is formed and a low-breakdown-voltage element region in which a low-breakdown-voltage element is formed are defined. An n+ buried diffusion layer and an n− epitaxial layer are formed on the p− semiconductor substrate. See, for example, Japanese Patent Application Publication No. JP 2007-220766 A (e.g., paragraph 0003 and FIG. 5).

However, in the high-voltage IC 200 manufactured by the self-separation IC process, a parasitic pnp bipolar transistor 118 including the p− diffusion region 203, the n− diffusion region 202, and the p-type bulk substrate 201 is formed in the high-side driving circuit region 210. The parasitic pnp bipolar transistor 118 has a base, an emitter, and a collector which are connected to the VB terminal, the VS terminal, and the GND terminal, respectively.

In the normal operation of the high-voltage IC 200, since the power supply potential VB is higher than the intermediate potential VS, the parasitic pnp bipolar transistor 118 does not operate. However, when the power supply potential VB is lower than the intermediate potential VS by 0.6 V or more, which is the diffusion potential of a silicon pn junction, or more due to a negative voltage surge, that is, when a potential relationship VB<(VS−0.6 [V]) is satisfied, the parasitic pnp bipolar transistor 118 is turned on. Then, a large amount of current flows between the VS terminal to which a high voltage (to the high-potential-side potential of Vdc) is applied and the GND terminal. Therefore, there is a concern that the high-voltage IC 200 will be broken down due to heat which is generated by the large amount of current.

In order to avoid the breakdown due to a surge, in general, a bypass capacitors which is connected between the VB terminal and the VS terminal is provided as an external component outside the p-type bulk substrate 201, as disclosed in the above-mentioned Non-patent Document 2. However, the bypass capacitor cannot be arranged due to restrictions in the layout design or costs or it is arranged at a position that is distant from the high-voltage IC 200 due to restrictions in the layout design. As a result, a sufficient effect is not obtained.

### SUMMARY OF THE INVENTION

The invention has been made in order to solve the above-mentioned problems of the related art and an object of the invention is to provide a semiconductor device which can prevent breakdown due to a surge.

In order to solve the above-mentioned problems and achieve the object of the invention, a semiconductor device according to an aspect of the invention has the following characteristics. A first semiconductor region of a second conductivity type to which a first potential is applied is provided in a surface layer of a semiconductor layer of a first conductivity type. A second semiconductor region of the first conductivity type to which a second potential is applied is provided in the first semiconductor region. A circuit that operates at a potential between the second potential, which is a reference potential, and the first potential higher than the second potential is provided in the first semiconductor region and the second semiconductor region. An insulated gate field effect transistor including a gate electrode that is formed on the surfaces of a source region of the first conductivity type which is selectively provided in the first semiconductor region, a drain region of the first conductivity type which is selectively provided in the first semiconductor region, and a portion of the first semiconductor region which is interposed between the source region and the drain region, with a gate insulating film interposed therebetween, is provided. The insulated gate field effect transistor has a threshold voltage of −0.1 V to −0.6 V. The source region and the gate electrode are electrically connected to the first semiconductor region. The drain region is electrically connected to the second semiconductor region.

The semiconductor device according to the above-mentioned aspect of the invention may further include an electric conductor that faces one side of the gate electrode which is opposite to the gate insulating film, with an insulator interposed therebetween. The electric conductor may be electrically connected to the drain region.

In the semiconductor device according to the above-mentioned aspect of the invention, the insulator may be made of a high-dielectric material.

In the semiconductor device according to the above-mentioned aspect of the invention, the insulator may be made of a zirconium oxide, a hafnium oxide, or a lanthanum oxide.

According to the invention, a clamping PMOS (insulated gate field effect transistor) that has a gate and a source electrically connected to a VB electrode to which a power supply potential VB of a high-side driving circuit is applied and a drain electrically connected to a VS electrode to which an intermediate potential VS, which is a reference potential of the high-side driving circuit is applied is provided in a high-side driving circuit region (first semiconductor region). According to this structure, a current can flow to the clamping PMOS when a negative voltage surge is applied. Therefore, it is possible to prevent the power supply potential VB from being lower than the intermediate potential VS by 0.6 V or more, which is the diffusion potential of a silicon pn junction, or more when the negative voltage surge is applied.

Thus, in a high-voltage IC which is manufactured by a self-isolation IC process using a p-type bulk substrate, it is possible to suppress the operation of a parasitic pnp bipolar transistor due to the negative voltage surge. As a result, it is possible to prevent a large amount of current from flowing between a VS terminal to which a high voltage (the high-potential-side potential of Vdc) and a GND terminal.

### EFFECT OF THE INVENTION

According to the semiconductor device of the invention, it is possible to prevent breakdown due to a surge.

### BRIEF DESCRIPTION OF DRAWINGS

FIG. 1 is a circuit diagram illustrating a semiconductor device according to Embodiment 1;

FIG. 2 is a plan view schematically illustrating the planar structure of the semiconductor device according to Embodiment 1;

FIG. 3 is a cross-sectional view illustrating a cross-sectional structure taken along the cutting line A-A′ of FIG. 2;

FIG. 4 is a cross-sectional view illustrating the state of the semiconductor device according to Embodiment 1 which is being manufactured;

FIG. 5 is a cross-sectional view illustrating the state of the semiconductor device according to Embodiment 1 which is being manufactured;

FIG. 6 is a cross-sectional view illustrating the state of the semiconductor device according to Embodiment 1 which is being manufactured;

FIG. 7 is a cross-sectional view illustrating the state of the semiconductor device according to Embodiment 1 which is being manufactured;

FIG. 8 is a cross-sectional view illustrating the state of the semiconductor device according to Embodiment 1 which is being manufactured;

FIG. 9 is a cross-sectional view illustrating the state of the semiconductor device according to Embodiment 1 which is being manufactured;

FIG. 10 is a cross-sectional view illustrating the state of the semiconductor device according to Embodiment 1 which is being manufactured;

FIG. 11 is a cross-sectional view illustrating the state of the semiconductor device according to Embodiment 1 which is being manufactured;

FIG. 12 is a cross-sectional view illustrating the state of the semiconductor device according to Embodiment 1 which is being manufactured;

FIG. 13 is a cross-sectional view illustrating the state of the semiconductor device according to Embodiment 1 which is being manufactured;

FIG. 14 is a cross-sectional view illustrating the state of the semiconductor device according to Embodiment 1 which is being manufactured;

FIG. 15 is a cross-sectional view illustrating the state of the semiconductor device according to Embodiment 1 which is being manufactured;

FIG. 16 is a cross-sectional view illustrating the state of the semiconductor device according to Embodiment 1 which is being manufactured;

FIG. 17 is a cross-sectional view illustrating the state of the semiconductor device according to Embodiment 1 which is being manufactured;

FIG. 18 is a circuit diagram illustrating a semiconductor device according to Embodiment 2;

FIG. 19 is a plan view schematically illustrating the cross-sectional structure of the semiconductor device according to Embodiment 2;

FIG. 20 is a characteristic diagram illustrating the electrical characteristics of a clamping p-channel MOSFET;

FIG. 21 is a characteristic diagram illustrating the electrical characteristics when the clamping p-channel MOSFET is turned on;

FIG. 22 is a characteristic diagram illustrating the electrical characteristics of the semiconductor device according to the embodiment when a negative voltage surge is applied.

FIG. 23 is a circuit diagram illustrating a high-voltage IC according to the related art;

FIG. 24 is a plan view schematically illustrating the planar structure of the high-voltage IC according to the related art; and

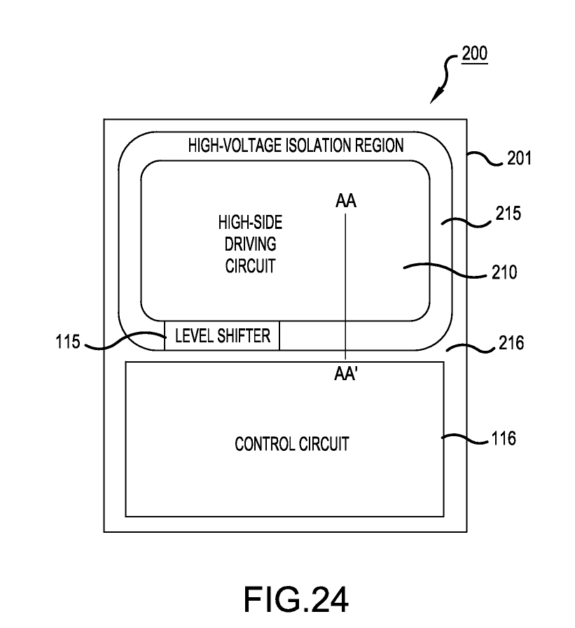

FIG. 25 is a cross-sectional view illustrating a cross-sectional structure taken along the cutting line AA-AN of FIG. 24.

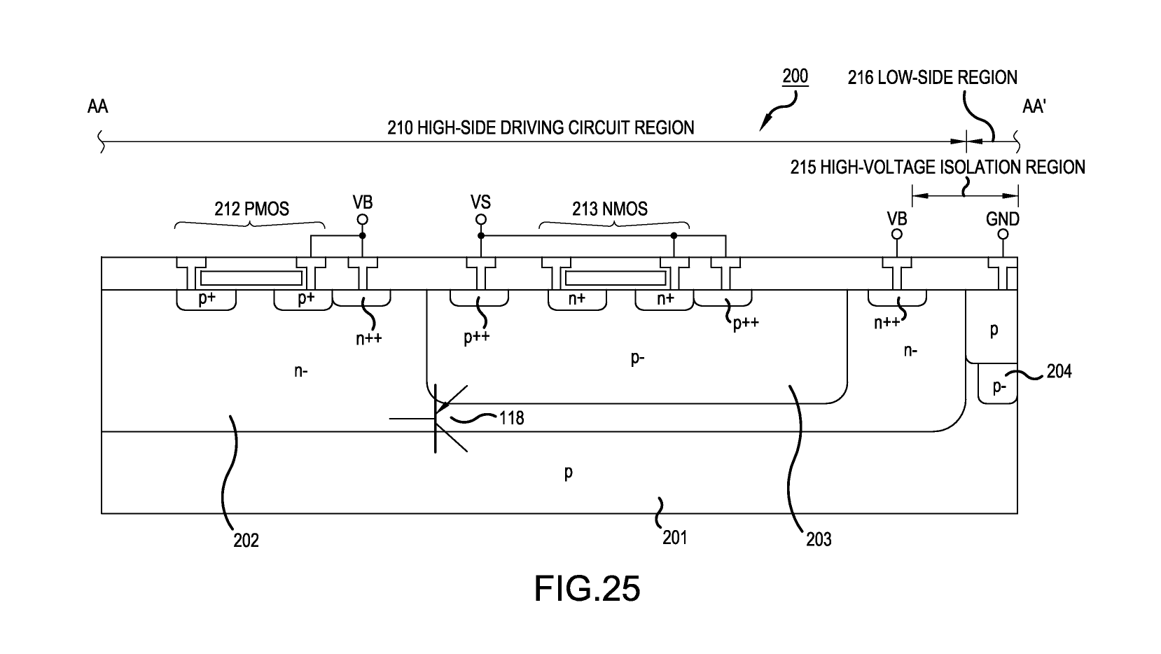

### DETAILED DESCRIPTION

Hereinafter, the preferred embodiments of a semiconductor device according to the invention will be described in detail with reference to the accompanying drawings. In the specification and the accompanying drawings, in the layers or regions having “n” or “p” appended thereto, an electron or a hole means a majority carrier. In addition, symbols “+” and “−” added to n or p mean that impurity concentration is higher and lower than that of the layer without the symbols. In the description of the following embodiments and the accompanying drawings, the same components are denoted by the same reference numerals and the description thereof will not be repeated.

### Embodiment 1

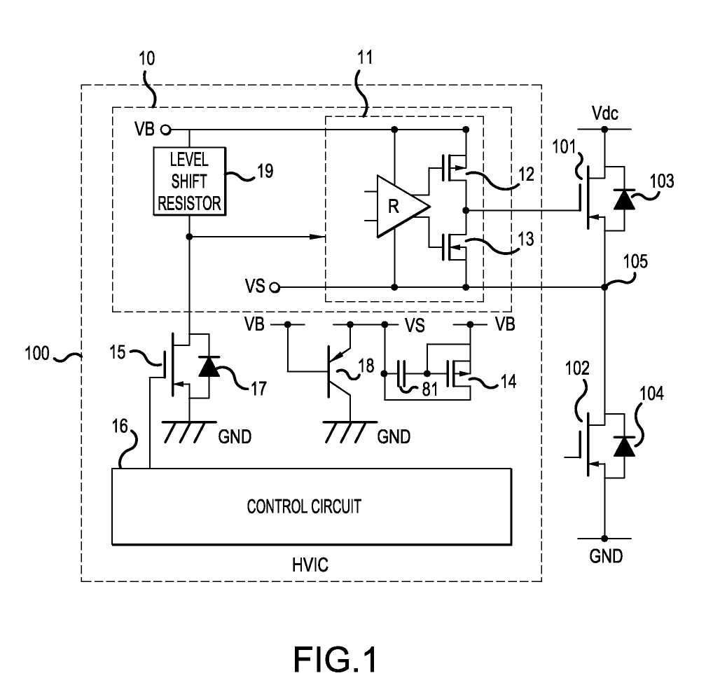

The structure of a semiconductor device according to Embodiment 1 will be described. FIG. 1 is a circuit diagram illustrating the semiconductor device according to Embodiment 1. The semiconductor device according to Embodiment 1 illustrated in FIG. 1 is a high-voltage IC 100 which drives first and second IGBTs 101 and 102 forming one phase of a power conversion bridge circuit (main circuit). As illustrated in FIG. 1, the high-voltage IC 100 includes a high-side driving circuit 10, a low-side driving circuit (not illustrated), a clamping enhancement-type p-channel MOSFET (hereinafter, referred to as a clamping PMOS) 14, a level shifter 15, and a control circuit 16.

The high-side driving circuit 10 includes, for example, a gate driving circuit 11, a NOT circuit, and a level shift resistor 19. The first and second IGBTs 101 and 102 are connected in series between a high-voltage main power supply (positive electrode side) Vdc and a ground potential GND which is on the negative electrode side of the main power supply. A VS terminal is connected to a connection point 105 between the first IGBT 101 and the second IGBT 102. The connection point 105 is an output point of a power conversion bridge circuit formed by the first and second IGBTs 101 and 102 and is connected to, for example, a motor which is a load.

When the first IGBT 101 and the second IGBT 102 are complementarily turned on and off while the high-voltage IC 100 is operating, an intermediate potential VS which is applied to the VS terminal repeatedly rises and drops between the high-potential-side potential (for example, about 400 V) and the low-potential-side potential (ground potential GND) of the main power supply Vdc and varies from 0 V to hundreds of volts. A power supply potential VB is about 15 V higher than the intermediate potential VS and is about 415 V higher than a substrate potential (ground potential GND).

The potential (intermediate potential) VS applied to the VS terminal is a reference potential and the high-side driving circuit 10 operates at a potential between the intermediate potential VS and the power supply potential VB and drives the high-side first IGBT 101. Specifically, the high-side driving circuit 10 inputs an on/off signal to a gate of the high-side first IGBT 101 through the NOT circuit and the gate driving circuit 11 provided on the rear side of the NOT circuit, using a voltage drop by the level shift resistor 19 as a signal.

The gate driving circuit 11 is a CMOS circuit in which a high-side p-channel MOSFET (PMOS) 12 and a low-side n-channel MOSFET (NMOS) 13 are connected so as to complement each other. Specifically, a source of the PMOS 12 is connected to a VB terminal and a drain of the PMOS 12 is connected to a drain of the NMOS 13. A source of the NMOS 13 is connected to the VS terminal. A connection point between the PMOS 12 and the NMOS 13 is connected to the gate of the first IGBT 101.

The clamping PMOS 14 is connected between the VB terminal and the VS terminal. Specifically, the source and gate of the clamping PMOS 14 are connected to the VB terminal. The drain of the clamping PMOS 14 is connected to the VS terminal. The threshold voltage of the clamping PMOS 14 is in the range of about −0.1 V to −0.6 V. It is preferable that the breakdown voltage of the clamping PMOS 14 be equal to or higher than 15 V. The term “threshold voltage” means a gate voltage at which the channel is changed from a weak inversion state to a strong inversion state when the gate voltage rises or drops from 0 V.

The control circuit 16 operates at the ground potential GND as a reference and generates a low-level on/off signal for turning on and off the first IGBT 101 and a low-level on/off signal for turning on and off the second IGBT 102. The level shifter 15 converts the low-level on/off signal generated by the control circuit 16 into a high-level on/off signal to be input to the gate of the first IGBT 101. Reference numerals 103, 104, and 17 denote a free-wheeling diode (FWD).

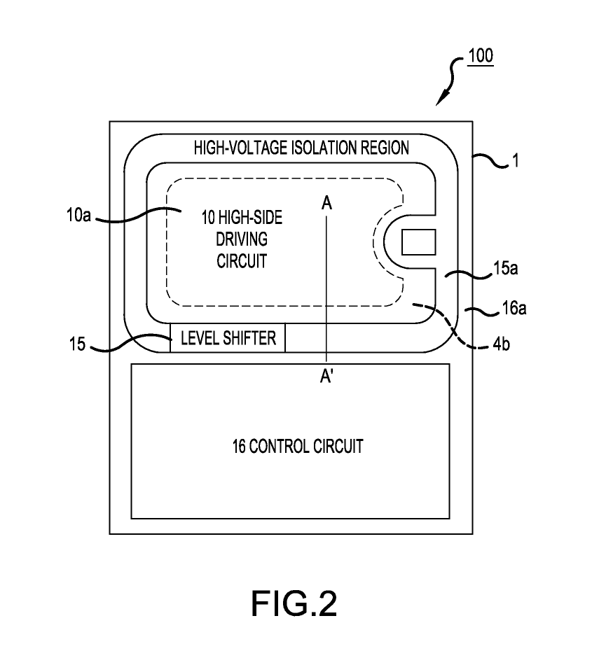

The high-voltage IC 100 is manufactured on a p-type bulk substrate by, for example, an IC process using a self-isolation technique. The planar structure of the high-voltage IC 100 will be described. FIG. 2 is a plan view schematically illustrating the planar structure of the semiconductor device according to Embodiment 1. As illustrated in FIG. 2, a p-type bulk substrate 1 includes a high-side driving circuit region 10a in which the high-side driving circuit 10 is arranged, a high-voltage isolation region 15a for ensuring the breakdown voltage of the high-side driving circuit 10, and a low-side region 16a which surrounds the high-voltage isolation region 15a.

The high-voltage isolation region 15a is arranged around the high-side driving circuit region 10a so as to surround the high-side driving circuit region 10a. The high-side driving circuit region 10a is separated from the low-side region 16a by the high-voltage isolation region 15a and a high potential that is higher than that applied to the low-side region 16a by 600 V or more can be applied to the high-side driving circuit region 10a. A VB electrode 4b is provided in the high-side driving circuit region 10a so as to surround the high-side driving circuit 10 in the vicinity of the boundary between the high-side driving circuit region 10a and the high-voltage isolation region 15a.

The VB electrode and the VS electrode (which are not illustrated) are selectively provided in the high-side driving circuit region 10a, depending on the design conditions of the high-voltage IC 100. Since the VB electrode and the VS electrode are arranged in the high-side driving circuit region 10a, it is possible to extract a carrier serving as noise. The level shifter 15 is arranged in the high-voltage isolation region 15a. The low-side region 16a is a portion other than the high-side driving circuit region 10a and a portion of the high-voltage isolation region 15a in which the level shifter 15 is formed. The control circuit 16 is arranged in the low-side region 16a. The level shifter 15 may be formed in the low-side region 16a.

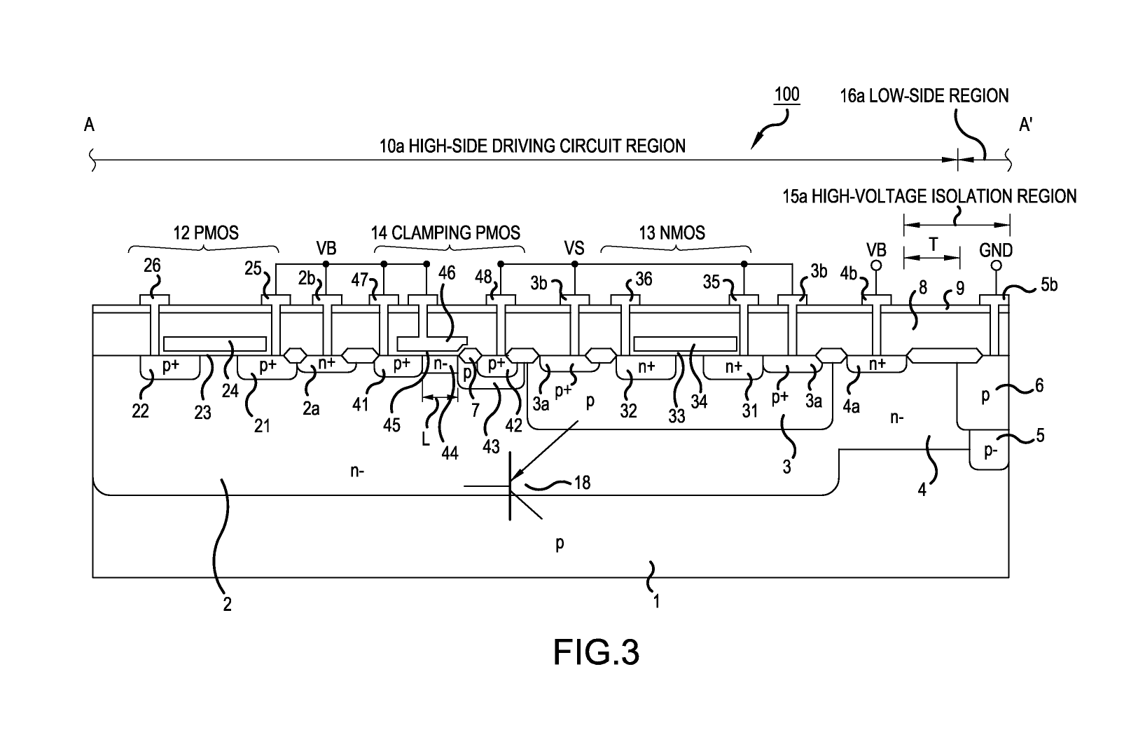

Next, the cross-sectional structure of the high-voltage IC 100 will be described. FIG. 3 is a cross-sectional view illustrating the cross-sectional structure taken along the cutting line A-A′ of FIG. 2. As illustrated in FIG. 3, the high-voltage IC 100 has an element isolation structure which is formed on the p-type bulk substrate 1 by a self-isolation IC process. An n− diffusion region 2 is selectively provided in a surface layer of the p-type bulk substrate 1. The n− diffusion region 2 is provided in the high-side driving circuit region 10a. The n− diffusion region 2 may have a diffusion depth of, for example, about 10 A p diffusion region 3 is selectively provided in a surface layer of the n− diffusion region 2.

The high-side driving circuit 10 is provided in the n− diffusion region 2 and the p diffusion region 3. The clamping PMOS 14 is provided in the n− diffusion region 2. FIG. 3 illustrates the lateral p-channel MOSFET (PMOS) 12 and the lateral n− channel MOSFET (NMOS) 13 forming the gate driving circuit 11 among the components of the high-side driving circuit 10. The power supply potential VB is applied to the n− diffusion region 2 from a VB electrode 2b which is electrically connected through an n+ high-concentration region 2a provided in the n− diffusion region 2. An intermediate potential VS (the potential of the connection point 105) is applied to the p diffusion region 3 from a VS electrode 3b which is electrically connected through a p+ high-concentration region 3a provided in the p diffusion region 3.

Specifically, the PMOS 12 is formed in a surface layer of the n− diffusion region 2. The PMOS 12 includes a p+ source region 21, a p+ drain region 22, a gate insulating film 23, a gate electrode 24, a source electrode 25, and a drain electrode 26. The p+ source region 21 and the p+ drain region 22 are provided in the n− diffusion region 2 so as to be separated from each other. The diffusion depth of the p+ source region 21 and the p+ drain region 22 is less than that of the p diffusion region 3. The gate electrode 24 is provided on the surface of a portion of the n− diffusion region 2 which is interposed between the p+ source region 21 and the p+ drain region 22, with the gate insulating film 23 interposed therebetween. The source electrode 25 and the drain electrode 26 are electrically connected to the p+ source region 21 and the p+drain region 22, respectively. The source electrode 25 is connected to the VB electrode 2b by, for example, an aluminum line.

The NMOS 13 is formed in a surface layer of the p diffusion region 3. The NMOS 13 includes an n+ source region 31, an n+ drain region 32, a gate insulating film 33, a gate electrode 34, a source electrode 35, and a drain electrode 36. The n+ source region 31 and the n+ drain region 32 are provided in the p diffusion region 3 so as to be separated from each other. The gate electrode 34 is provided on the surface of a portion of the p diffusion region 3 which is interposed between the n+ source region 31 and the n+ drain region 32, with the gate insulating film 33 interposed therebetween. The source electrode 35 and the drain electrode 36 are electrically connected to the n+ source region 31 and the n+ drain region 32, respectively. The source electrode 35 is connected to the VS electrode 3b by, for example, an aluminum line.

The clamping PMOS 14 is formed in a surface layer of the n− diffusion region 2. The clamping PMOS 14 includes a p+ source region 41, a p+ drain region 42, a p drain drift region 43, an n− channel region 44, a gate insulating film 45, a gate electrode 46, a source electrode 47, and a drain electrode 48. In the clamping PMOS 14, the p+ source region 41 and the p+ drain region 42 are provided in the n− diffusion region 2 so as to be separated from each other. The diffusion depth of the p+ source region 41 and the p+ drain region 42 is less than that of the p diffusion region 3. The p drain drift region 43 is provided in the n− diffusion region 2 so as to cover the p+ drain region 42.

The n− channel region 44 is provided between the p+ source region 41 and the p drain drift region 43. The gate electrode 46 is provided on the surface of a portion of the n− diffusion region 2 which is interposed between the p+ source region 41 and the p+ drain region 42, with the gate insulating film 45 interposed therebetween. The source electrode 47 and the drain electrode 48 are electrically connected to the p+source region 41 and the p+ drain region 42, respectively. The gate electrode 46 and the source electrode 47 are connected to the VB electrode 2b by, for example, aluminum lines. The drain electrode 48 is connected to the VS electrode 3b by, for example, an aluminum line.

The clamping PMOS 14 may have, for example, a channel length L of 1.7 and a channel width W of 25000 The channel length L of the clamping PMOS 14 means the shortest distance between the p+ source region 41 and the p drain drift region 43. The channel width W of the clamping PMOS 14 means the width of a channel portion in a direction perpendicular to the channel length L. FIG. 3 illustrates the clamping PMOS 14 between the PMOS 12 and the NMOS 13. However, the clamping PMOS 14 may be arranged in the high-side driving circuit region 10a and be electrically connected between the VB terminal and the VS terminal. In addition, as the arrangement area of the clamping PMOS 14 increases, the effect of the invention is improved.

For example, an n− diffusion region 4 is provided outside the n− diffusion region 2 in the surface layer of the p-type bulk substrate 1 at a depth that is less than that of the n− diffusion region 2. The n− diffusion region 4 comes into contact with the n− diffusion region 2 and surrounds the n− diffusion region 2. The power supply potential VB is applied to the n− diffusion region 4 from a VB electrode 4b which is connected through an n+ high-concentration region 4a in the n− diffusion region 4. The n+ high-concentration region 4a and the VB electrode 4b surround the high-side driving circuit region 10a. The high-side driving circuit region 10a extends from the n− diffusion region 2 to the outer end of the n+ high-concentration region 4a.

A p− region 5 is provided outside the n− diffusion region 4 in the surface layer of the p-type bulk substrate 1 so as to surround the n− diffusion region 4 and to come into contact with the n− diffusion region 4. A p region 6 is provided in the n− diffusion region 4 and the p− region 5 at the boundary between the n− diffusion region 4 and the p− region 5. The p− region (hereinafter, referred to as a p− GND region) 5 and the p region (hereinafter, referred to as a p GND region) 6 are supplied with the ground potential GND from a GND electrode 5b which is electrically connected through a p+ high-concentration region (not illustrated) in the p GND region 6. The p− GND region 5 and the p GND region 6 have a function of fixing the p-type bulk substrate 1 to the ground potential GND.

The n− diffusion region 4, the p− GND region 5, and the p GND region 6 form the high-voltage isolation region 15a. Specifically, the high-voltage isolation region 15a extends from the outer end of the n+ high-concentration region 4a to the outer end of the p− GND region 5. A distance T from the outer end of the n+ high-concentration region 4a to the inner end of the p GND region 6 is about 100 μm when the breakdown voltage is 600 V and is about 200 μm when the breakdown voltage is 1200 V.

The low-side region 16a is a portion which is disposed outside the outer end of the n+ high-concentration region 4a except the portion in which a shift register (not illustrated) is formed. Reference numeral 7 denotes a local insulating film such as local oxidation of silicon (LOCOS). Reference numeral 8 denotes an interlayer insulating film such as boro-phospho-silicate glass (BPSG). Reference numeral 9 denotes a passivation film which is a silicon nitride film (Si3N4 film).

The high-voltage IC 100 is manufactured by an IC process (self-isolation IC process) using a self-isolation technique, which will be described below. Therefore, a parasitic pnp bipolar transistor 18 which has the p diffusion region 3 as an emitter, the n− diffusion region 2 as a base, and the p-type bulk substrate 1 as a collector is formed in the high-side driving circuit region 10a. The base, emitter, and collector of the parasitic pnp bipolar transistor 18 are connected to the VB terminal, the VS terminal, and the GND terminal, respectively.

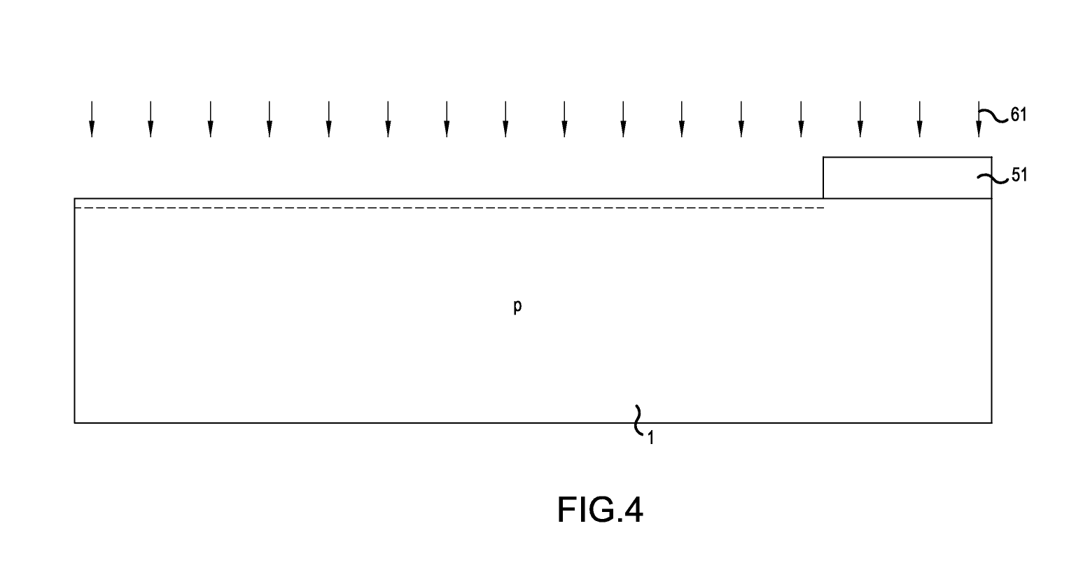

Next, a method for manufacturing the high-voltage IC 100 will be described. A process for manufacturing the clamping PMOS 14 will be mainly described. FIGS. 4 to 17 are cross-sectional views illustrating the state of the semiconductor device according to Embodiment 1 which is being manufactured. First, as illustrated in FIG. 4, the p-type bulk substrate 1 which is made of silicon with a specific resistance of, for example, about 300 Ωcm is prepared. Then, a resist mask 51 is formed on the surface of the p-type bulk substrate 1 such that a portion corresponding to a region for forming the n− diffusion region 2 is exposed.

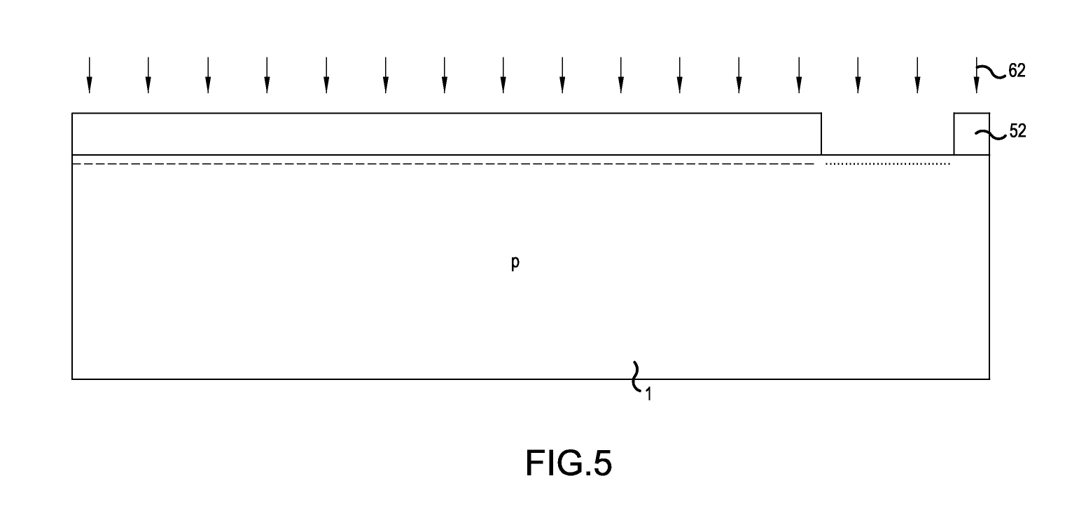

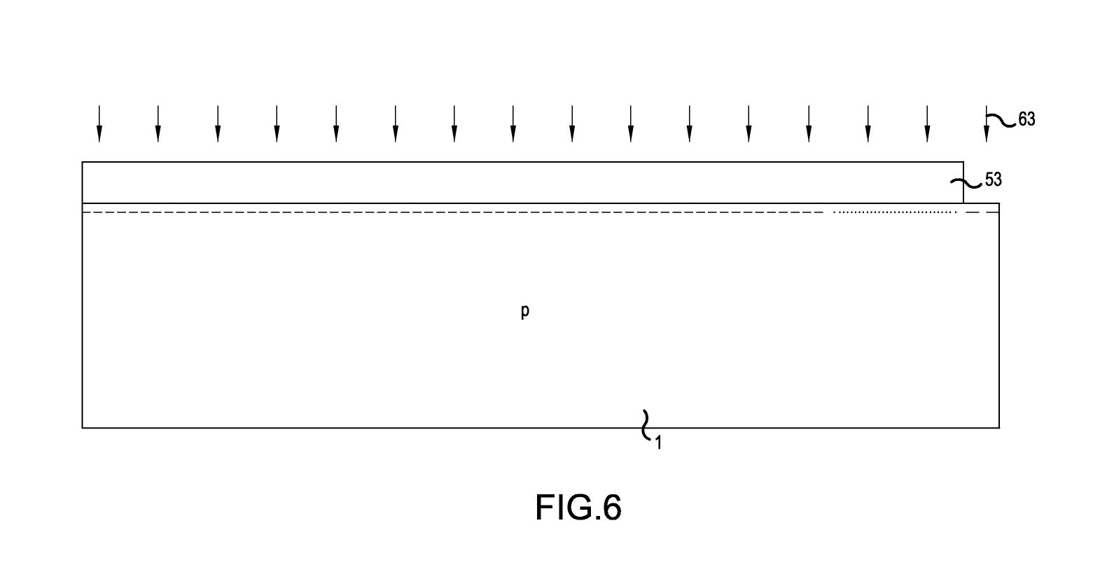

Then, a first ion implantation process 61 using n-type impurities, such as phosphorus (P), is performed using the resist mask 51 as a mask. In FIG. 4, a dotted line in the vicinity of the surface of the p-type bulk substrate 1 indicates the n− type impurities which are implanted by the first ion implantation process 61 (which holds for FIGS. 5 and 6). In the first ion implantation process 61, an acceleration voltage and a dose may be, for example, about 50 keV and about 2.0×1013/cm2, respectively.

Then, as illustrated in FIG. 5, the resist mask 51 is removed and a resist mask 52 is formed on the surface of the p-type bulk substrate 1 such that a portion corresponding to the region for forming the n− diffusion region 4 is exposed. Then, a second ion implantation process 62 using n-type impurities, such as phosphorus, is performed using the resist mask 52 as a mask. In the second ion implantation process 62, an acceleration voltage and a dose may be, for example, about 50 keV and about 4.0×1012/cm2, respectively. In FIG. 5, a dotted line (a dotted line that is thinner than the dotted line indicating the n-type impurities implanted by the first ion implantation process 61) in the vicinity of the surface of the p-type bulk substrate 1 indicates the n-type impurities which are implanted by the second ion implantation process 62 (which holds for FIG. 6).

Then, as illustrated in FIG. 6, the resist mask 52 is removed and a resist mask 53 is formed on the surface of the p-type bulk substrate 1 such that a portion corresponding to a region for forming the p− GND region 5 is exposed. Then, a third ion implantation process 63 using p-type impurities, such as boron (B), is performed using the resist mask 53 as a mask. In the third ion implantation process 63, an acceleration voltage and a dose may be, for example, about 50 keV and about 3.0×1012/cm2.

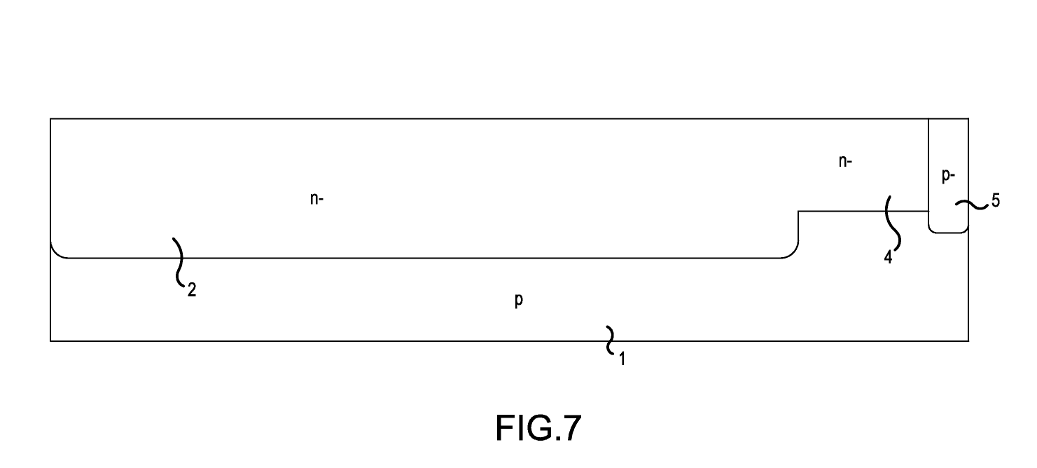

In FIG. 6, a dotted line (a dotted line that is coarser than the dotted lines indicating the n-type impurities implanted by the first and second ion implantation processes 61 and 62) in the vicinity of the surface of the p-type bulk substrate 1 indicates the p-type impurities which are implanted by the third ion implantation process 63. Then, the resist mask 53 is removed and a heat treatment is performed, for example, in a nitrogen (N2) atmosphere at a temperature of about 1200° C. for about 300 minutes to thermally diffuse the n-type impurities and the p-type impurities implanted into the p-type bulk substrate 1 by the first to third ion implantation processes 61 to 63. In this way, as illustrated in FIG. 7, the n− diffusion region 2, the n− diffusion region 4, and the p− GND region 5 are formed.

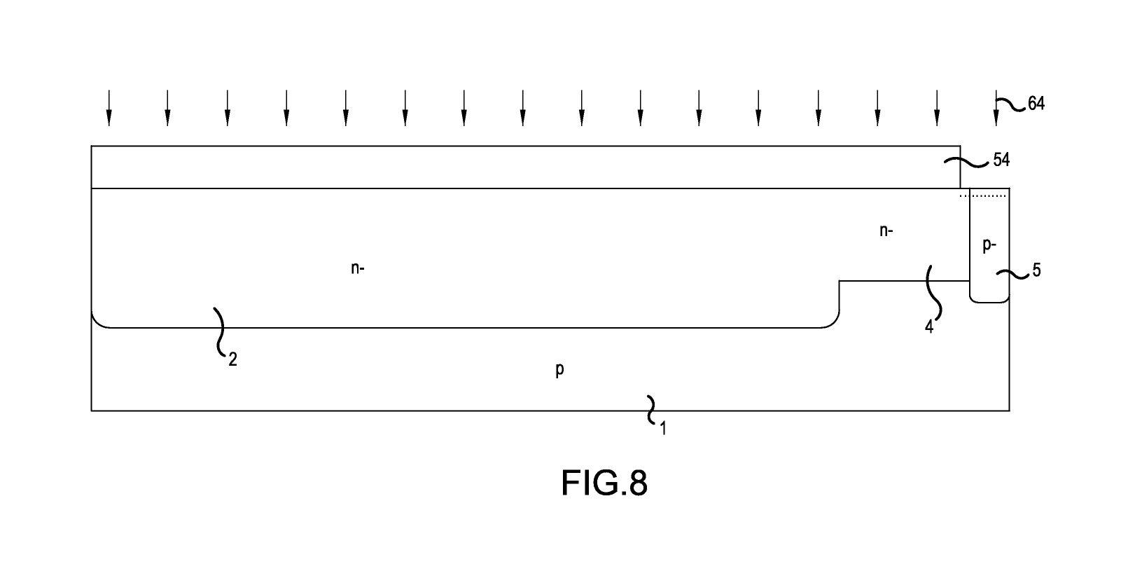

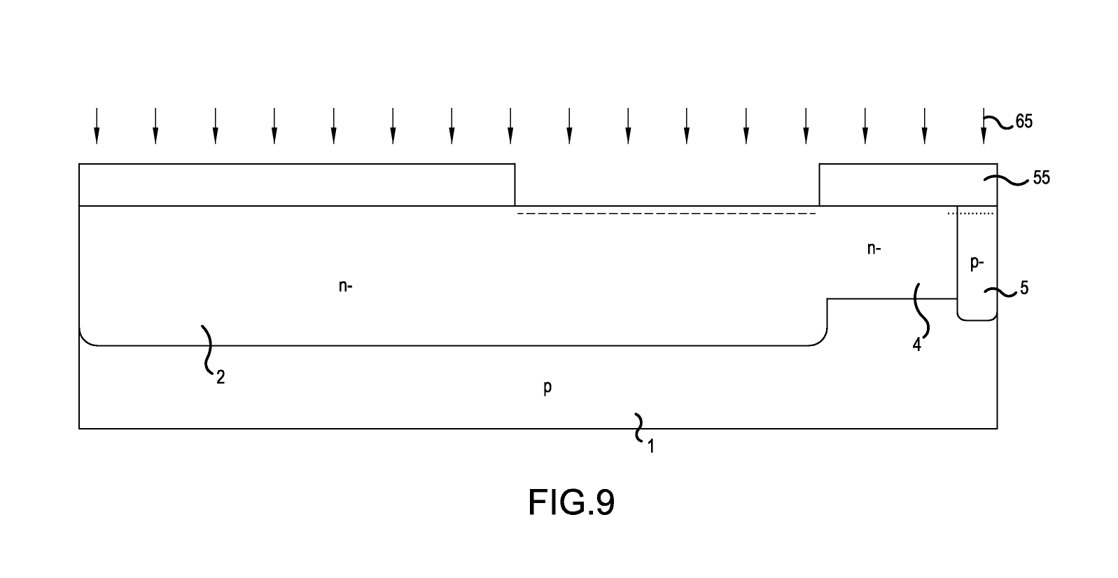

Then, as illustrated in FIG. 8, a resist mask 54 is formed on the surface of the p-type bulk substrate 1 in which the n− diffusion region 2 is formed (hereinafter, simply referred to as a surface) and a portion corresponding to a region for forming the p GND region 6 is exposed. Then, a fourth ion implantation process 64 using p-type impurities, such as boron, is performed using the resist mask 54 as a mask. In the fourth ion implantation process 64, an acceleration voltage and a dose may be, for example, about 50 keV and about 4.0×1013/cm2, respectively. In FIG. 8, a dotted line in the vicinity of the surface of the p− GND region 5 indicates the p-type impurities implanted by the fourth ion implantation process 64 (which holds for FIG. 9).

Then, as illustrated in FIG. 9, the resist mask 54 is removed and a resist mask 55 is formed on the surface of the p-type bulk substrate 1 such that a portion corresponding to a region for forming the p diffusion region 3 is exposed. Then, a fifth ion implantation process 65 using p-type impurities, such as boron, is performed using the resist mask 55 as a mask. In the fifth ion implantation process 65, an acceleration voltage and a dose may be, for example, about 50 keV and about 5.0×1013/cm2.

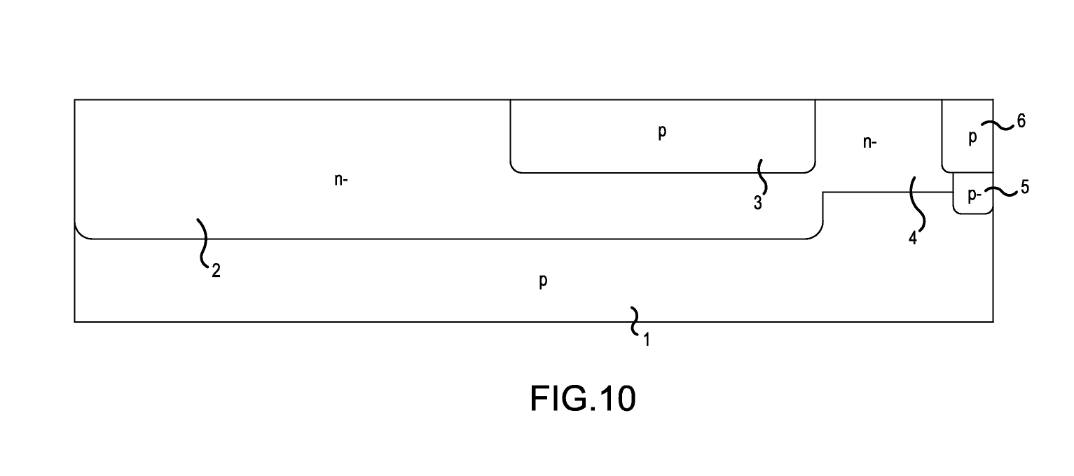

In FIG. 9, a dotted line (a dotted line that is coarser than the dotted line indicating the p-type impurities implanted by the fourth ion implantation process 64) in the vicinity of the surface of the n− diffusion region 2 indicates the p-type impurities implanted by the fifth ion implantation process 65. Then, the resist mask 55 is removed and a heat treatment is performed, for example, in a nitrogen atmosphere at a temperature of about 1150° C. for about 240 minutes to thermally diffuse the p-type impurities implanted into the p-type bulk substrate 1 by the fourth and fifth ion implantation processes 64 to 65. In this way, as illustrated in FIG. 10, the p diffusion region 3 and the p GND region 6 are formed.

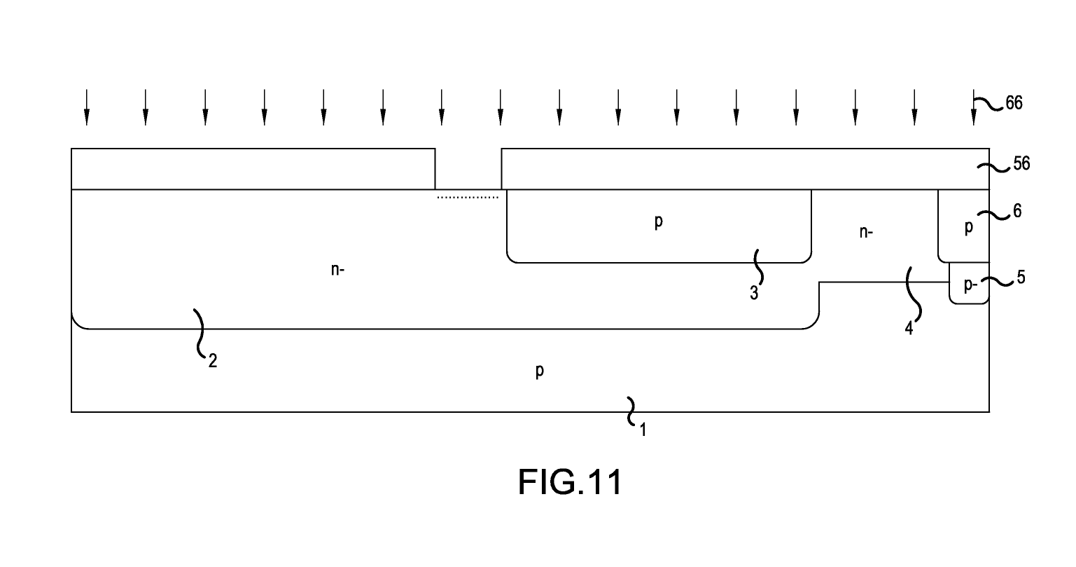

Then, as illustrated in FIG. 11, a resist mask 56 is formed on the surface of the p-type bulk substrate 1 such that a portion corresponding to a region for forming the p drain drift region 43 of the clamping PMOS 14 is exposed. Then, a sixth ion implantation process 66 using p-type impurities, such as boron, is performed using the resist mask 56 as a mask. In the sixth ion implantation process 66, an acceleration voltage and a dose may be, for example, about 50 keV and about 4.0×1013/cm2. In FIG. 11, a dotted line in the vicinity of the surface of the n− diffusion region 2 indicates the p-type impurities which are implanted by the sixth ion implantation process 66.

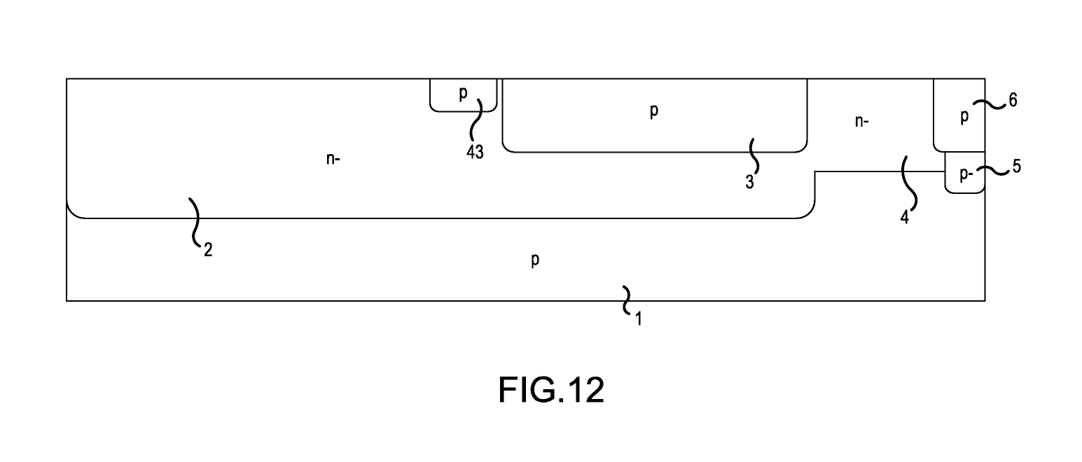

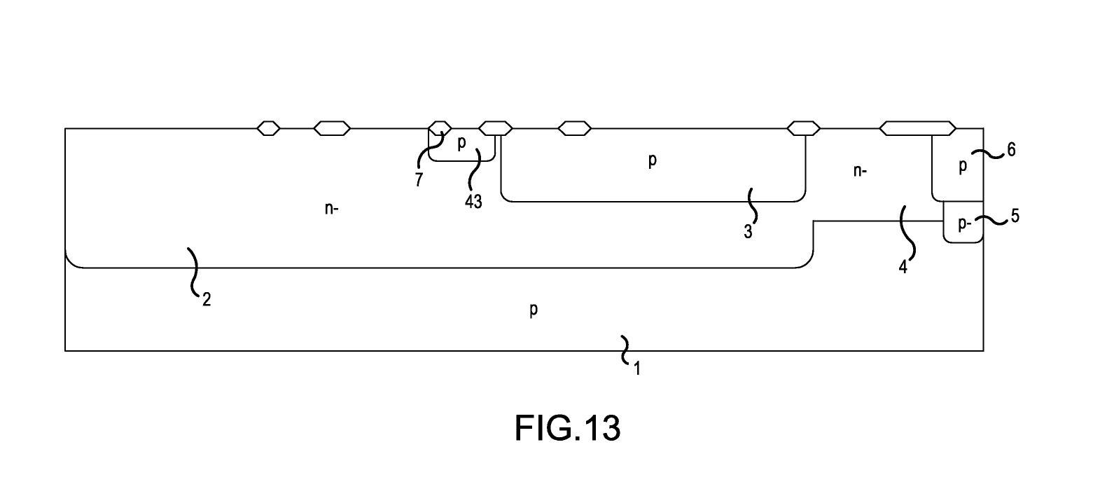

Then, the resist mask 56 is removed and a heat treatment is performed, for example, in a nitrogen atmosphere at a temperature of about 1150° C. for about 90 minutes to thermally diffuse the p-type impurities implanted into the p-type bulk substrate 1 by the sixth ion implantation process 66. In this way, as illustrated in FIG. 12, the p drain drift region 43 is formed. Then, as illustrated in FIG. 13, a heat treatment is performed, for example, in an oxygen (O2) atmosphere at a temperature of about 1000° C. for about 90 minutes to form the local insulating film 7.

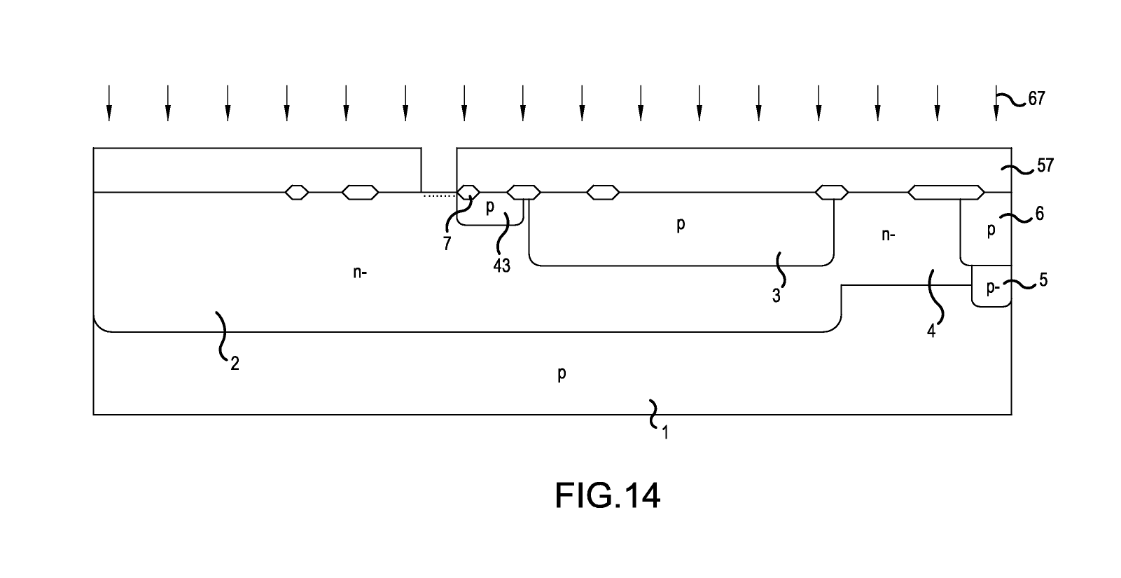

Then, as illustrated in FIG. 14, a resist mask 57 is formed on the surface of the p-type bulk substrate 1 such that a portion corresponding to a region for forming the n− channel region 44 of the clamping PMOS 14 is exposed. Then, a seventh ion implantation process 67 using p-type impurities, such as boron, is performed using the resist mask 57 as a mask. In the seventh ion implantation process 67, an acceleration voltage and a dose may be, for example, about 120 keV and about 1.0×1012/cm2. In FIG. 14, a dotted line in the vicinity of the surface of the n− diffusion region 2 indicates the p-type impurities implanted by the seventh ion implantation process 67. The n− type impurity concentration of a portion of the n− diffusion region 2 which corresponds to the region for forming the n− channel region 44 is reduced by the p-type impurities implanted by the seventh ion implantation process 67.

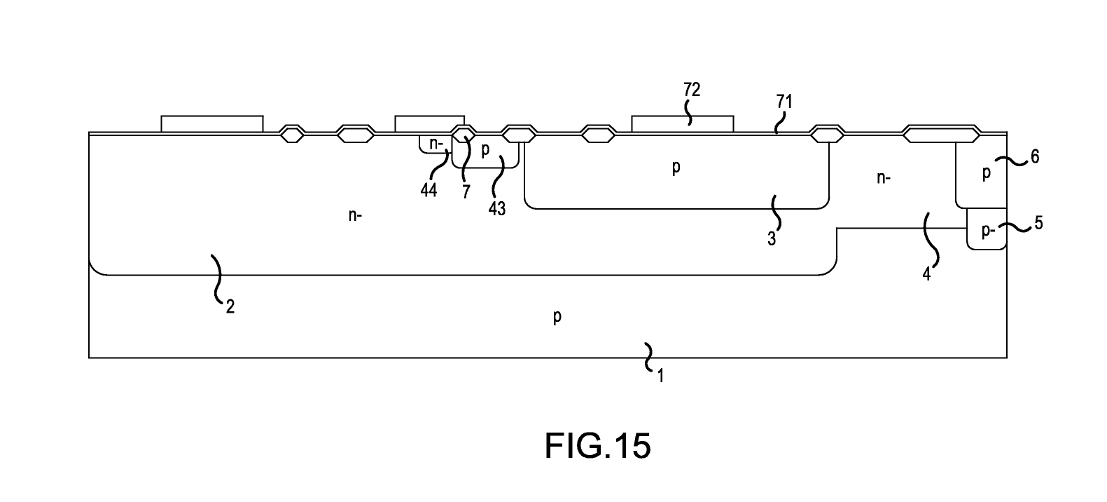

Then, as illustrated in FIG. 15, thermal oxidation is performed in an oxygen atmosphere to form a silicon oxide film 71 with a thickness of 50 Å on the surface of the p-type bulk substrate 1. The silicon oxide film 71 becomes the gate insulating films 23, 33, and 45. Then, a doped polysilicon film 72 is formed with a thickness of 3000 Å on the silicon oxide film 71 by a reduced pressure chemical vapor deposition (CVD) method and is then patterned. In this way, the gate electrodes 24, 34, and 46 are formed.

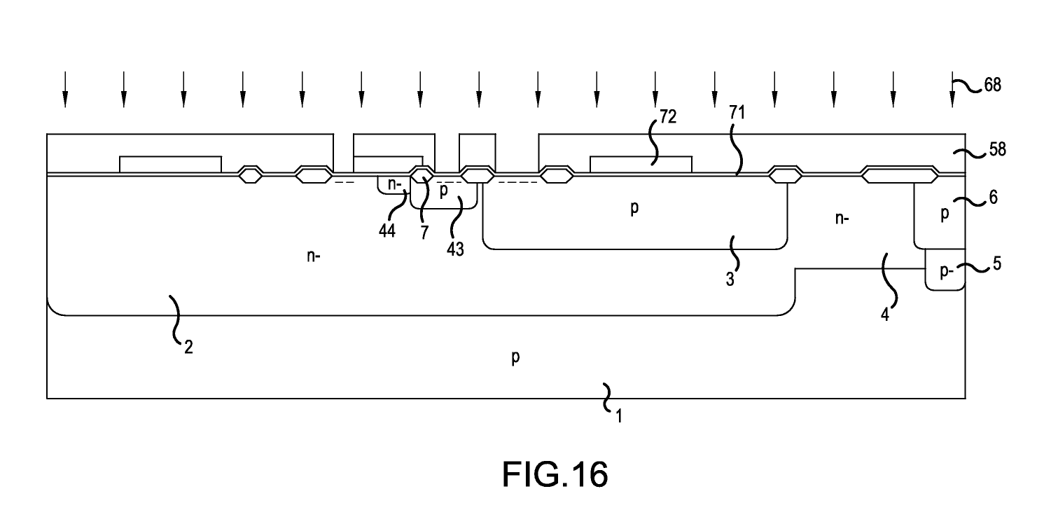

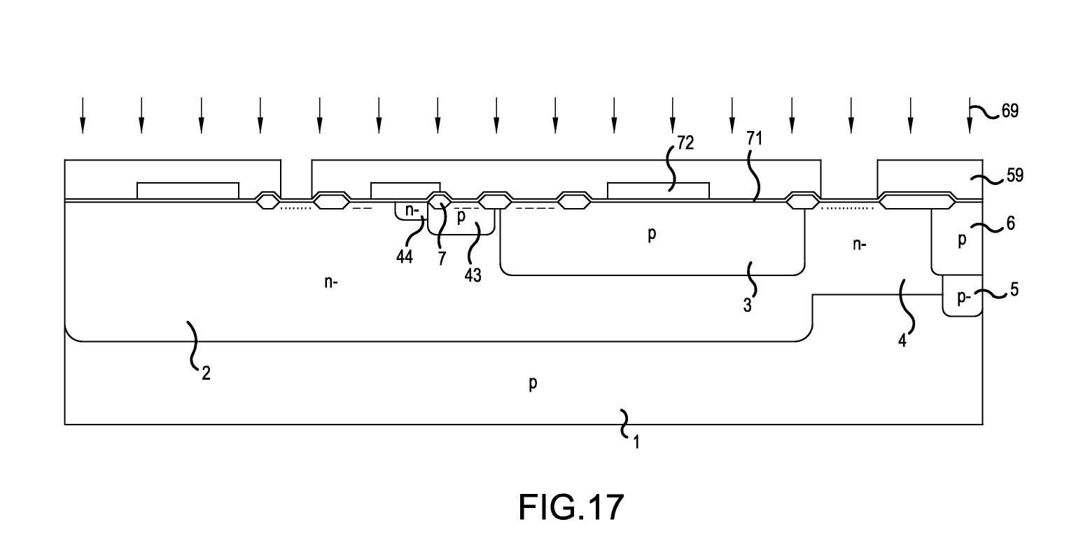

Then, as illustrated in FIG. 16, a resist mask 58 is formed on the surface of the p-type bulk substrate 1 and portions corresponding to a region for forming the p+source region 41 and the p+ drain region 42 of the clamping PMOS 14 and a region for forming the p+ high-concentration region 3a are exposed. Then, an eighth ion implantation process 68 using p-type impurities, such as boron, is performed using the resist mask 58 as a mask. In the eighth ion implantation process 68, an acceleration voltage and a dose may be, for example, about 65 keV and about 3.0×1015/cm2. In this case, the eighth ion implantation process 68 is also performed on a portion corresponding to a region for forming the p+ high-concentration region (not illustrated) in the p GND region 6. In FIG. 16, a dotted line in the vicinity of the surfaces of the n− diffusion region 2, the p diffusion region 3, and the p drain drift region 43 indicates the p-type impurities implanted by the eighth ion implantation process 68 (which holds for FIG. 17).

Then, as illustrated in FIG. 17, the resist mask 58 is removed and a resist mask 59 is formed on the surface of the p-type bulk substrate 1 such that a portion corresponding to a region for forming the n+ high-concentration region 2a and the n+ high-concentration region 4a is exposed. Then, a ninth ion implantation process 69 using n-type impurities, such as arsenic (As), is performed using the resist mask 59 as a mask. In the ninth ion implantation process 69, an acceleration voltage and a dose may be, for example, about 65 keV and about 4.0×1015/cm2, respectively. In FIG. 17, a dotted line (a dotted line that is thinner than the dotted line indicating the p-type impurities implanted by the eighth ion implantation process 68) in the vicinity of the surfaces of the n− diffusion region 2 and the n− diffusion region 4 indicates the n-type impurities implanted by the ninth ion implantation process 69.

Then, the resist mask 59 is removed and a heat treatment is performed to thermally diffuse the n-type impurities and the p-type impurities implanted into the p-type bulk substrate 1 by the seventh to ninth ion implantation processes 67 to 69. In this way, as illustrated in FIG. 3, the n− channel region 44, the p+ source region 41, the p+ drain region 42, the p+ high-concentration region 3a, the n+ high-concentration region 2a, the n+ high-concentration region 4a, and the p+ high-concentration region (not illustrated) in the p GND region 6 are formed. Then, an interlayer insulating film 8 with a thickness of 1.0 μm is deposited by a CVD method. Then, the interlayer insulating film 8 is selectively removed by photolithography and a plurality of contact holes are formed.

Then, an aluminum (Al) film with a thickness of, for example, 1.0 μm is deposited on the interlayer insulating film 8. The aluminum film comes into contact with the p+ source region 41, the p+ drain region 42, the p+ high-concentration region 3a, the n+ high-concentration region 2a, the n+ high-concentration region 4a, and the p+ high-concentration region (not illustrated) in the p GND region 6 through each contact hole. Then, the aluminum film is patterned to form the source electrode 47, the drain electrode 48, the VB electrode 2b, the VS electrode 3b, the GND electrode 5b, and the aluminum lines (not illustrated).

Then, the passivation film 9 with a thickness of 1.0 μm is formed by a plasma CVD method. In this way, the high-voltage IC 100 illustrated in FIGS. 1 to 3 is completed. For example, the PMOS 12, the NMOS 13, a resistor, and a capacitor are formed on the p-type bulk substrate 1 having the clamping PMOS 14 formed thereon by adding a general manufacturing method to the method for manufacturing the high-voltage IC 100. The time when the PMOS 12, the NMOS 13, the resistor, and the capacitor (capacitance) are formed can vary depending on the design conditions of the high-voltage IC 100. Each region of the PMOS 12 and the NMOS 13 may be formed together with a region of the clamping PMOS 14 which has the same diffusion depth and impurity concentration as the PMOS 12 and the NMOS 13.

Next, the operation of the high-voltage IC 100 when the high-side first IGBT 101 is driven will be described. The control circuit 16 generates a low-level on/off signal. The low-level on/off signal is input to the high-side driving circuit 10 through the level shifter 15. The high-side driving circuit 10 operates at a potential between the intermediate potential VS, which is a reference potential, and the power supply potential VB. While the high-voltage IC 100 is operating, the potential applied to the VS terminal changes from 0 V to hundreds of volts. For example, the power supply potential VB is about 15 V higher than the intermediate potential VS.

The on/off signal which is input to the high-side driving circuit 10 is input to the gate of the high-side first IGBT 101 through the NOT circuit and the gate driving circuit 11 provided on the rear side of NOT circuit. The first IGBT 101 is turned on and off on the basis of the on/off signal from the control circuit 16. Since the power supply potential VB is higher than the intermediate potential VS in the normal operation of the high-voltage IC 100, the parasitic pnp bipolar transistor 18 does not operate. In addition, since the power supply potential VB is higher than the intermediate potential VS, the clamping PMOS 14 is turned off and no current flows to the clamping PMOS 14.

In contrast, when a negative voltage surge is applied and the power supply potential VB is lower than the intermediate potential VS by the absolute value of the threshold voltage of the clamping PMOS 14 or more, the clamping PMOS 14 is turned on and a current flows from the VS electrode 3b to the VB electrodes 2b and 4b through the clamping PMOS 14. Therefore, it is possible to reduce a base current which flows between the base and the emitter of the parasitic pnp bipolar transistor 18. The current which flows to the clamping PMOS 14 when the power supply potential VB is lower than the intermediate potential VS by 0.6 V or more is caused by the turn-off of the parasitic pn diode formed by the p+ drain region 42 and the n− diffusion region 2 which is a back gate.

The current which flows to the clamping PMOS 14 when the power supply potential VB is lower than the intermediate potential VS by the absolute value of the threshold voltage or more is caused by the channel current of the clamping PMOS 14. The reason why the channel current of the clamping PMOS 14 flows will be described. It is assumed that the clamping PMOS 14 is a PMOS (hereinafter, referred to as a reverse clamping PMOS) which has the p+ source region 41 as the drain, the p+ drain region 42 as the source, and the n− diffusion region 2 as the back gate. Since the channel has bidirectionality, the application of a gate voltage equal to or more than a threshold voltage to the source enables a drain current to flow from the source to the drain even in the reverse clamping PMOS, similarly to a general MOSFET.

In the high-voltage IC 100, the reverse clamping PMOS is in the state in which the drain, the gate, and the back gate are connected to the VB terminal and the source is connected to the VS terminal. Therefore, when the power supply potential VB is lower than the intermediate potential VS by the absolute value of the threshold voltage of the clamping PMOS 14 or more, a voltage that is equal to or more than the absolute value of the threshold voltage is applied between the gate and the source of the reverse clamping PMOS. Therefore, the clamping PMOS is turned on and the channel current of the clamping PMOS 14 flows. In this case, the potential of the n− diffusion region 2, which is the back gate of the reverse clamping PMOS is reduced due to a reduction in the power supply potential VB. As a result, the threshold voltage of the reverse clamping PMOS is lower than the threshold voltage of the clamping PMOS 14 by the back gate effect.

As described above, according to Embodiment 1, the clamping PMOS that includes the gate and source electrically connected to the VB electrode to which the power supply potential VB of the high-side driving circuit is applied and the drain electrode electrically connected to the VS electrode to which the intermediate potential VS, which is the reference potential of the high-side driving circuit, and has a threshold voltage of about −0.1 V to −0.6 V is provided in the high-side driving circuit region. Therefore, a current can flow to the clamping PMOS when a negative voltage surge is applied. When the negative voltage surge is applied, it is possible to prevent the power supply potential VB from being lower than the intermediate potential VS by 0.6 V or more, which is the diffusion potential of a silicon pn junction, or more. Therefore, in the high-voltage IC which is manufactured by the self-isolation IC process using the p− type bulk substrate, it is possible to suppress the operation of the parasitic pnp bipolar transistor due to the negative voltage surge. As a result, it is possible to prevent a large amount of current from flowing between the VS terminal to which a high voltage (to the high-potential-side potential of Vdc) is applied and the GND terminal and to prevent the breakdown of the high-voltage IC.

In addition, according to Embodiment 1, the high-voltage IC can be manufactured at a low cost only by ion implantation and thermal diffusion, using an inexpensive bulk substrate and the self-isolation IC process which does not require a special element isolation process. In addition, it is not necessary to provide, as an external component, a bypass capacitor which connects the VB terminal and the VS terminal. Therefore, it is possible to provide an inexpensive high-voltage IC.

According to Embodiment 1, a PMOS or an NMOS forming the gate driving circuit and a clamping PMOS can be formed in the high-side driving circuit region. Therefore, it is possible to improve the effect of avoiding breakdown due to a negative voltage surge. In addition, since the clamping PMOS can be formed in the high-side driving circuit region, it is possible to improve the effect of avoiding breakdown due to a negative voltage surge even when a bypass capacitor which is an external component for connecting the VB terminal and the VS terminal is not provided or even when the distance is long. Therefore, it is possible to improve flexibility in the layout design.

### Embodiment 2

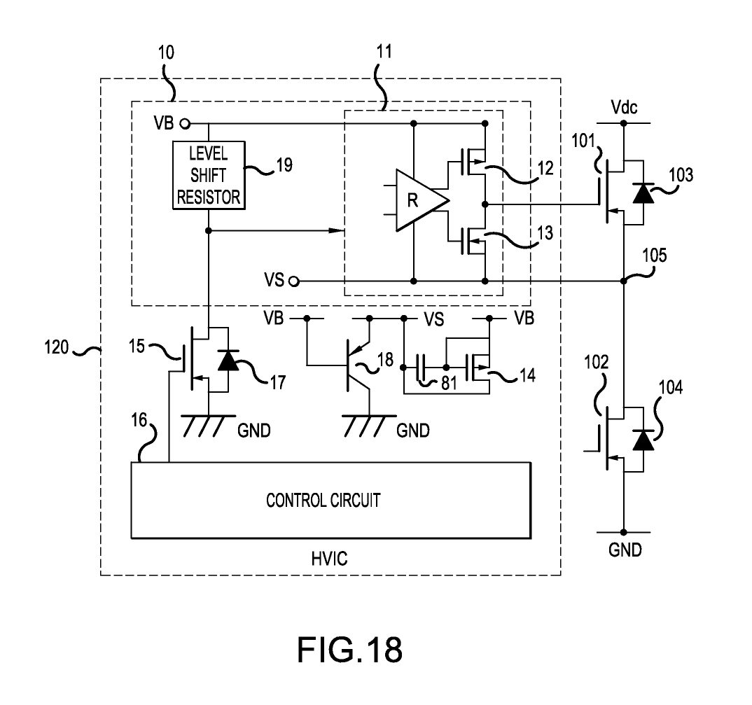

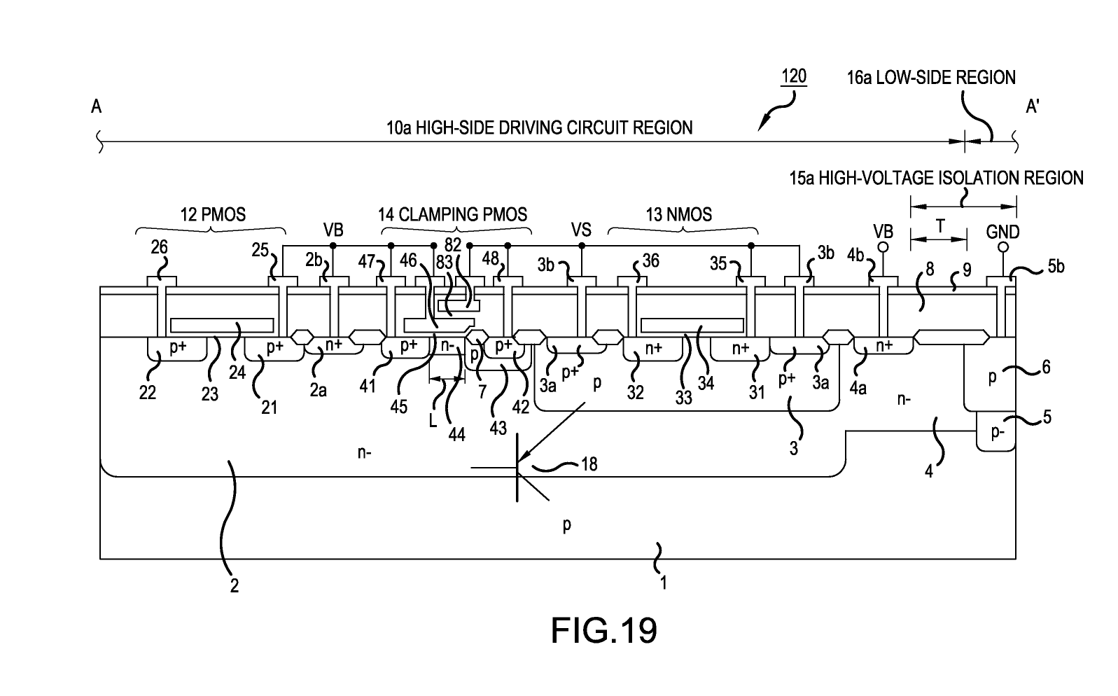

The structure of a semiconductor device according to Embodiment 2 will be described. FIG. 18 is a circuit diagram illustrating the semiconductor device according to Embodiment 2. FIG. 19 is a plan view schematically illustrating the cross-sectional structure of the semiconductor device according to Embodiment 2. The planar structure of the semiconductor device according to Embodiment 2 is the same as that of the semiconductor device according to Embodiment 1. That is, FIG. 19 illustrates the cross-sectional structure taken along the cutting line A-A′ of FIG. 2. A high-voltage IC 120 according to Embodiment 2 differs from the high-voltage IC 100 according to Embodiment 1 in that a bypass capacitor 81 is connected between a VB terminal and a VS terminal (FIG. 18).

As illustrated in FIG. 19, the bypass capacitor 81 is formed in the vicinity of a gate electrode 46 of a clamping PMOS 14 in an interlayer insulating film 8. Specifically, the bypass capacitor 81 is formed by the gate electrode 46 of the clamping PMOS 14, an insulating film 83, and an electric conductor (hereinafter, referred to as a capacitor electrode) 82. The capacitor electrode 82 is provided on the side of the gate electrode 46 which is opposite to a gate insulating film 45, with the insulating film 83 interposed therebetween. In addition, the capacitor electrode 82 is connected to a VS electrode 3b by, for example, an aluminum line. That is, the capacitor electrode 82 is electrically connected to a p+ drain region 42 of the clamping PMOS 14, with low resistance therebetween.

It is preferable that the insulating film 83 be made of a high-dielectric material, such as a zirconium oxide (ZrO2), a hafnium oxide (HfO2), or a lanthanum oxide (La2O3). This is because it is possible to increase the capacitance of the bypass capacitor 81. The thickness of the insulating film 83 may be, for example, 250 Å. The provision of the bypass capacitor 81 enables a current to flow from the VS electrode 3b to VB electrodes 2b and 4b through the bypass capacitor 81 as well as the clamping PMOS 14 even when a negative voltage surge is applied and a power supply potential VB is lower than an intermediate potential VS by the absolute value of the threshold voltage of the clamping PMOS 14 or more.

As described above, according to Embodiment 2, it is possible to obtain the same effect as that in Embodiment 1. According to Embodiment 2, the provision of the bypass capacitor makes it possible to prevent the power supply potential VB from being lower than the intermediate potential VS. Therefore, the semiconductor device according to Embodiment 2 has a high effect on a device without a bypass capacitor, such as an intelligent power module (IPM), according to the related art. In addition, according to Embodiment 2, a PMOS or an NMOS forming a gate driving circuit and a bypass capacitor can be formed in a high-side driving circuit region. Therefore, it is possible to improve the effect of preventing breakdown due to a negative voltage surge even when a bypass capacitor is connected as an external component.

### Example

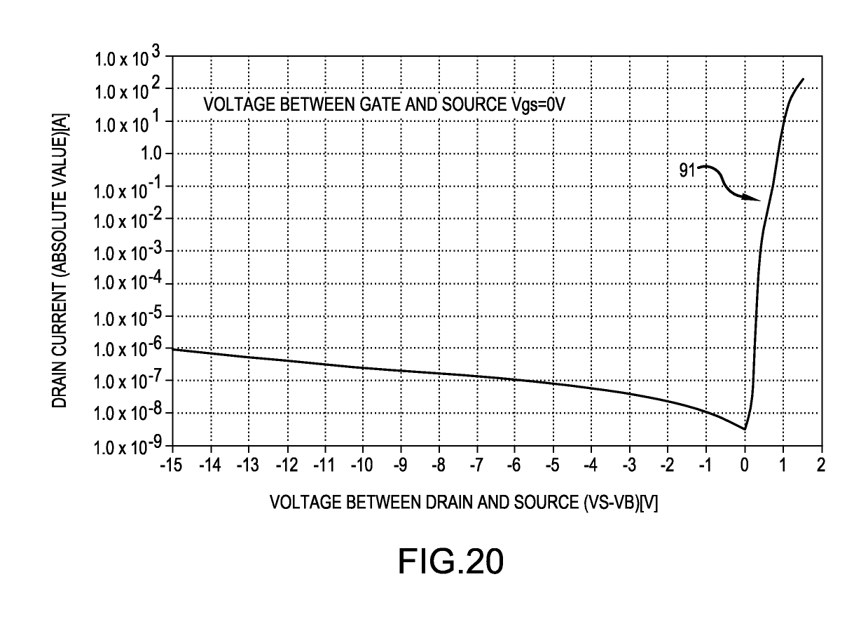

Next, the operation of the clamping PMOS 14 of the semiconductor device according to the invention was verified using the high-voltage IC (hereinafter, referred to as an example) according to Embodiment 1. FIG. 20 is a characteristic diagram illustrating the electrical characteristics of a clamping p-channel MOSFET. FIG. 20 illustrates the relationship between a drain current and a voltage between the drain and the source (a voltage between the VS terminal and the VB terminal) when a voltage Vgs between the gate and the source of the clamping PMOS 14 is 0 V. The threshold voltage of the clamping PMOS 14 was −0.15 V. The area of the parasitic pnp bipolar transistor 18 was 0.2 mm2 as in a general high-voltage IC. As illustrated in FIG. 20, when the voltage between the drain and the source is less than the absolute value of the threshold voltage of the clamping PMOS 14, that is, 0.15 V, no current flows between the drain and the source of the clamping PMOS 14.

In contrast, when the drain potential of the clamping PMOS 14 is higher than a source potential by 0.15 V or more, an inversion layer is formed in the n− channel region 44 and a current flows between the drain and the source of the clamping PMOS 14. A current which flows when the voltage between the drain and the source is in the range of 0.0 V to 0.6 V is the channel current of the clamping PMOS 14 (a voltage of 0.6 V between the drain and the source is represented by an arrow 91). In addition, a current which flows when the voltage between the drain and the source is equal to or higher than 0.6 V is a current which flows to a parasitic pn diode formed by the n− diffusion region 2 and the p+ drain region 42 of the clamping PMOS 14.

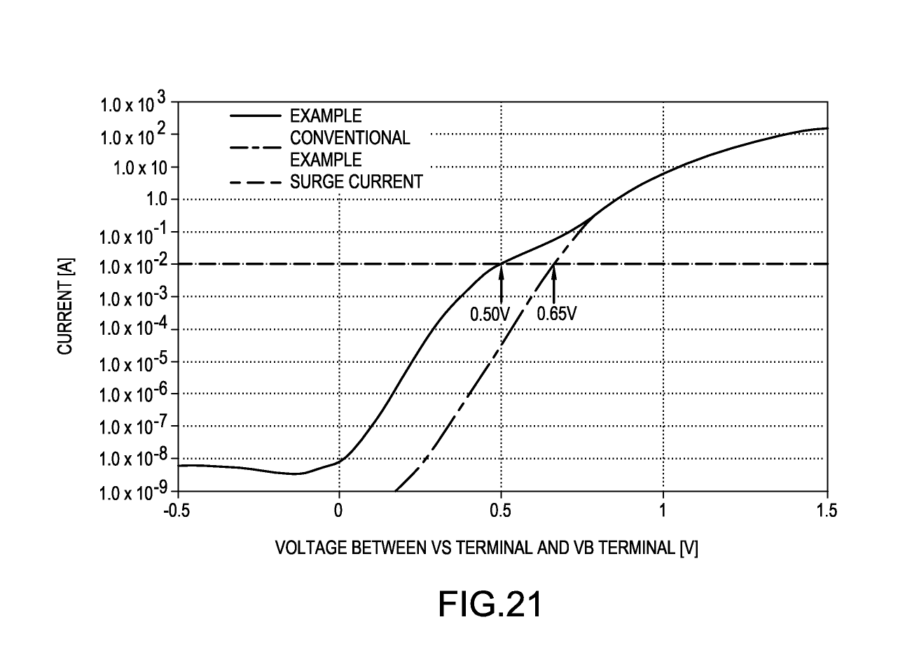

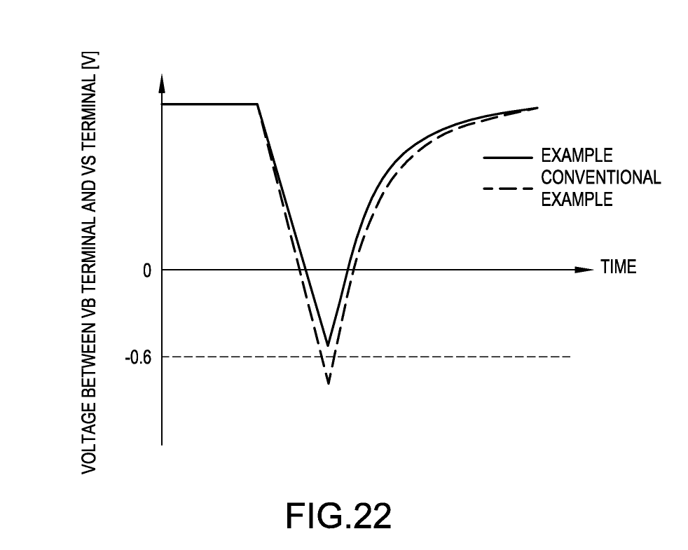

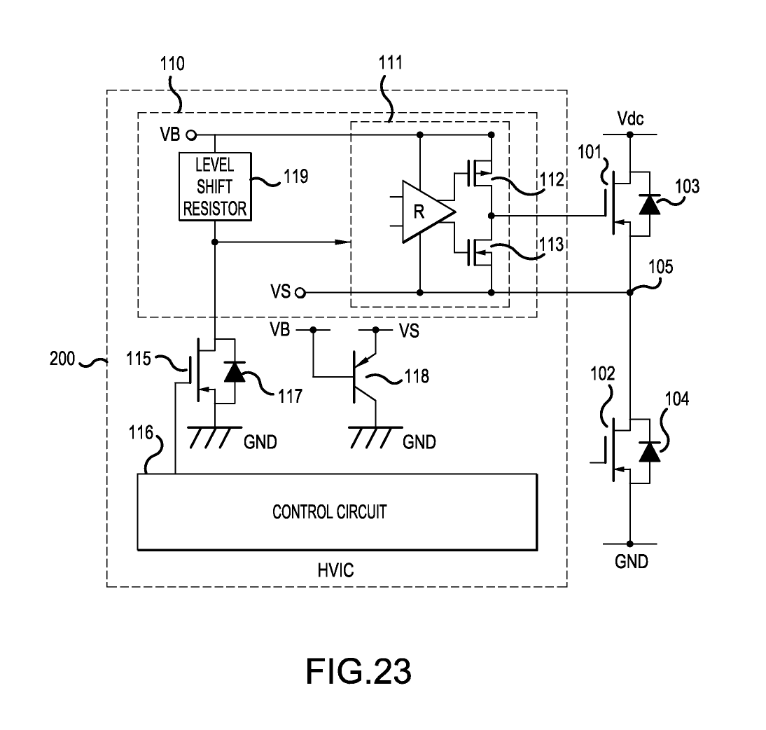

FIG. 21 is a characteristic diagram illustrating electrical characteristics when the clamping p-channel MOSFET is turned off. FIG. 22 is a characteristic diagram illustrating electrical characteristics when a negative voltage surge is applied to the semiconductor device according to the example. In FIG. 21, a voltage between the VS terminal and the VB terminal indicated by the horizontal axis is a value obtained by subtracting the power supply potential VB from the intermediate potential VS (=the intermediate potential VS−the power supply potential VB). In FIG. 22, a voltage between the VB terminal and the VS terminal indicated by the vertical axis is a value obtained by subtracting the intermediate potential VS from the power supply potential VB (=the power supply potential VB−the intermediate potential VS). As illustrated in FIG. 21, in the case in which the clamping PMOS 14 is not provided as in the high-voltage IC according to the related art (see FIG. 23; hereinafter, referred to as a conventional example), it was confirmed that, when a surge voltage was applied and a base current (surge current) of 10 mA flowed between the base and the emitter of the parasitic pnp bipolar transistor 118, the power supply potential VB was 0.65 V lower than the intermediate potential VS. Therefore, as illustrated in FIG. 22, in the conventional example, it was confirmed that the power supply potential VB was lower than the intermediate potential VS by 0.6 V or more.

In the high-voltage IC (example) according to Embodiment 1, it was confirmed that, when the drain electrode 48 of the clamping PMOS 14 was connected to the VS electrode 3b, the source electrode 47 was connected to the VB electrode 2b, and the power supply potential VB was 0.15 V lower than the intermediate potential VS, the drain current (surge current) flowed from the VS electrode 3b to the VB electrode 2b through the clamping PMOS 14 and the power supply potential VB was only 0.50 V lower than the intermediate potential VS. That is, in the example, it was confirmed that the base current of the parasitic pnp bipolar transistor 18 could be suppressed to one hundredth (=1.0×10−4/1.0×10−2) of that in the conventional example. Therefore, in the example, it was confirmed that, since the power supply potential VB was not less than the intermediate potential VS by 0.6 V or more, the parasitic pnp bipolar transistor 18 did not operate, as illustrated in FIG. 22.

Various modifications and changes of the invention can be made. In each of the above-described embodiments, for example, the dimensions of each portion are set depending on, for example, required specifications.

As described above, the semiconductor devices according to the invention are useful for a power semiconductor device that is used in power conversion devices, such as inverters, or power supply devices, such as various industrial machines.

What is claimed is:

1. A semiconductor device comprising:
a semiconductor layer of a first conductivity type;
a first semiconductor region of a second conductivity type which is provided in a surface layer of the semiconductor layer and to which a first potential is applied;
a second semiconductor region of the first conductivity type which is provided in the first semiconductor region and to which a second potential is applied;
a circuit that is provided in the first semiconductor region and the second semiconductor region and operates at a potential between the second potential, which is a reference potential, and the first potential higher than the second potential; and
an insulated gate field effect transistor including a gate electrode that is formed on the surfaces of a source region of the first conductivity type which is selectively provided in the first semiconductor region, a drain region of the first conductivity type which is selectively provided in the first semiconductor region, and a portion of the first semiconductor region which is interposed between the source region and the drain region, with a gate insulating film interposed therebetween,
wherein the insulated gate field effect transistor has a threshold voltage of −0.1 V to −0.6 V,
the source region and the gate electrode are electrically connected to the first semiconductor region, and
the drain region is electrically connected to the second semiconductor region.

2. The semiconductor device according to claim 1, further comprising:
an electric conductor that faces one side of the gate electrode which is opposite to the gate insulating film, with an insulator interposed therebetween,
wherein the electric conductor is electrically connected to the drain region.

3. The semiconductor device according to claim 2,
wherein the insulator is made of a high-dielectric material.

4. The semiconductor device according to claim 2,
wherein the insulator is made of a zirconium oxide, a hafnium oxide, or a lanthanum oxide.

5. The semiconductor device according to claim 3,
wherein the insulator is made of a zirconium oxide, a hafnium oxide, or a lanthanum oxide.
